(19) United States
(12) Patent Application Publication
(10) Pub. No.: US 2026/0043842 A1
(43) Pub. Date: Feb. 12, 2026

(54) CIRCUIT BOARD MEASUREMENT KIT AND CIRCUIT BOARD MEASUREMENT METHOD

(71) Applicants: Unimicron Technology Corp., Taoyuan City (TW); YUAN ZE UNIVERSITY, Taoyuan City (TW)

(72) Inventors: Chien-Chang HUANG, Taoyuan City (TW); Yu-Chen LIU, Taoyuan City (TW); Pin-Xian LIU, Taoyuan City (TW); Chun-Jui HUANG, Taoyuan City (TW); Yi-Pin LIN, Taoyuan City (TW); Wei-Yu LIAO, Taoyuan City (TW); Chi-Min CHANG, Taoyuan City (TW); Ching-Sheng CHEN, Taoyuan City (TW)

(21) Appl. No.: 18/976,374

(22) Filed: Dec. 11, 2024

(30) Foreign Application Priority Data
Aug. 12, 2024 (TW) 113130191

(51) Int. Cl. G01R 31/28

(52) U.S. Cl. CPC G01R 31/2818

(57) ABSTRACT

A circuit board measurement kit and a circuit board measurement method are provided. The circuit board measurement method includes: measuring a first measuring scattering parameter of a first measurement circuit board using one-port measurement; measuring a second measuring scattering parameter of a second measurement circuit board using one-port measurement; measuring a third measuring scattering parameter of a third measurement circuit board using one-port measurement; and calculating a characteristic impedance value, a terminal inductance impedance value, and a propagation constant of a coaxial via of a circuit board according to the first measuring scattering parameter, the second measuring scattering parameter, and the third measuring scattering parameter.

### CROSS-REFERENCE TO RELATED APPLICATION

This application claims priority to Taiwan Application Serial Number 113130191, filed Aug. 12, 2024. The above-mentioned patent application is herein incorporated by reference in its entirety.

### BACKGROUND

### Technical Field

The present disclosure relates to a circuit board measurement kit and a circuit board measurement method, which use a one-side and one-port measurement method and calculate an electrical parameter of a circuit board according to measurement results.

### Description of Related Art

In the existing multi-layer circuit boards, since the coaxial vias have good electromagnetic shielding effects, the coaxial vias are often used to transmit signals between the upper and lower wiring layers. As the signal transmission develops to high speed and high frequency, the electrical parameters of the coaxial vias can affect the signal integrity of the transmission, so that it is necessary to consider proper electrical parameters of the coaxial vias.

In the existing technology, to obtain the electrical parameters of the coaxial vias, it is necessary to prepare the equipment capable of performing the double-side measurement and a two-port instrument (e.g., network analyzer) to perform the measurement, which requires additional funds to prepare the equipment and the instrument, and the configuration of the instrument and the measurement procedures are more complex.

### SUMMARY

At least one embodiment of the disclosure provides a circuit board measurement kit which provides measurement tools capable of using one-side and one-port measurement to calculate an electrical parameter of a coaxial via of a circuit board.

The circuit board measurement kit provided in the at least one embodiment of the disclosure includes three measurement circuit boards. Each of the three measurement circuit boards comprises four wiring layers, a conductor pole, a metal wall, and a transmission line. The four wiring layers, in order from top to bottom, are a first wiring layer, a second wiring layer, a third wiring layer, and a fourth wiring layer. The conductor pole penetrates the four wiring layers and is connected to the first wiring layer and the fourth wiring layer. The metal wall extends from the third wiring layer to the fourth wiring layer and surrounds the conductor pole. The transmission line is electrically connected to the conductor pole. A surface of one of the four wiring layers is flush with a surface of the transmission line. In the first of the measurement circuit boards, the surface of the transmission line is flush with a surface of the first wiring layer, and the transmission line is electrically connected to a ground portion of the first wiring layer. There is a first measuring scattering parameter between the transmission line and the fourth wiring layer. In the second of the measurement circuit boards, the surface of the transmission line is flush with a surface of the second wiring layer, and the transmission line is electrically connected to a ground portion of the second wiring layer. There is a second measuring scattering parameter between the transmission line and the fourth wiring layer. In the third of the measurement circuit boards, the surface of the transmission line is flush with a surface of the third wiring layer, and the transmission line is electrically connected to the metal wall. There is a third measuring scattering parameter between the transmission line and the fourth wiring layer. An electrical parameter of a coaxial via of a circuit board is calculated according to the first measuring scattering parameter, the second measuring scattering parameter, and the third measuring scattering parameter.

At least one embodiment of the disclosure provides a circuit board measurement method suitable for calculating an electrical parameter of a coaxial via of a circuit board through one-side and one-port measurement results.

The circuit board measurement method provided in the at least one embodiment of the disclosure includes: measuring a first measuring scattering parameter of a first measurement circuit board using one-port measurement; measuring a second measuring scattering parameter of a second measurement circuit board using one-port measurement; measuring a third measuring scattering parameter of a third measurement circuit board using one-port measurement; and calculating a characteristic impedance value, a terminal inductance impedance value, and a propagation constant of a coaxial via of a circuit board according to the first measuring scattering parameter, the second measuring scattering parameter and the third measuring scattering parameter.

Based on the above, the circuit board measurement kit and the circuit board measurement method according to the above embodiments can indirectly calculate the electrical parameter of the coaxial via using the one-side and one-port measurement results, compared to the double-side and two-port measurement, thereby simplifying the configuration of the equipment, the necessary functions of the instrument, and the complexity of the measurement.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial sectioned view of a circuit board.

FIG. 2 is a sectioned view of a first measurement circuit board according to at least one embodiment of the present disclosure.

FIG. 3 is a sectioned view of a second measurement circuit board according to at least one embodiment of the present disclosure.

FIG. 4 is a sectioned view of a third measurement circuit board according to at least one embodiment of the present disclosure.

FIG. 5 is a sectioned view of an auxiliary measurement circuit board according to at least one embodiment of the present disclosure.

FIG. 6 is a flowchart of a circuit board measurement method according to at least one embodiment of the present disclosure.

FIG. 7 is a flowchart of sub-steps of step S660 of the circuit board measurement method of FIG. 6.

FIGS. 8 and 9 are calculation results of real parts and imaginary parts, respectively, of the characteristic impedance values of the circuit board in FIG. 1 as calculated.

FIGS. 10 and 11 are calculation results of attenuation constants and equivalent dielectric constants, respectively, corresponding to the propagation constants of the circuit board in FIG. 1 as calculated.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, substrates, and areas) in the drawings will be enlarged in unusual proportions, and the quantity of some elements will be reduced. Accordingly, the description and explanation of the following embodiments are not limited to the quantity, sizes and shapes of the elements presented in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case which are mainly for illustration are intended neither to accurately depict the actual shape of the elements nor to limit the scope of patent applications in this case.

Moreover, the words, such as “about”, “approximately”, or “substantially”, appearing in the present disclosure not only cover the clearly stated values and ranges, but also include permissible deviation ranges as understood by those with ordinary knowledge in the technical field of the disclosure. The permissible deviation range can be caused by the error generated during the measurement, where the error is caused by such as the limitation of the measurement system or the process conditions. In addition, “about” may be expressed within one or more standard deviations of the values, such as within +30%, +20%, +10%, or +5%. The word “about”, “approximately” or “substantially” appearing in this text can choose an acceptable deviation range or a standard deviation according to optical properties, etching properties, mechanical properties or other properties, not just one standard deviation to apply all the optical properties, etching properties, mechanical properties and other properties.

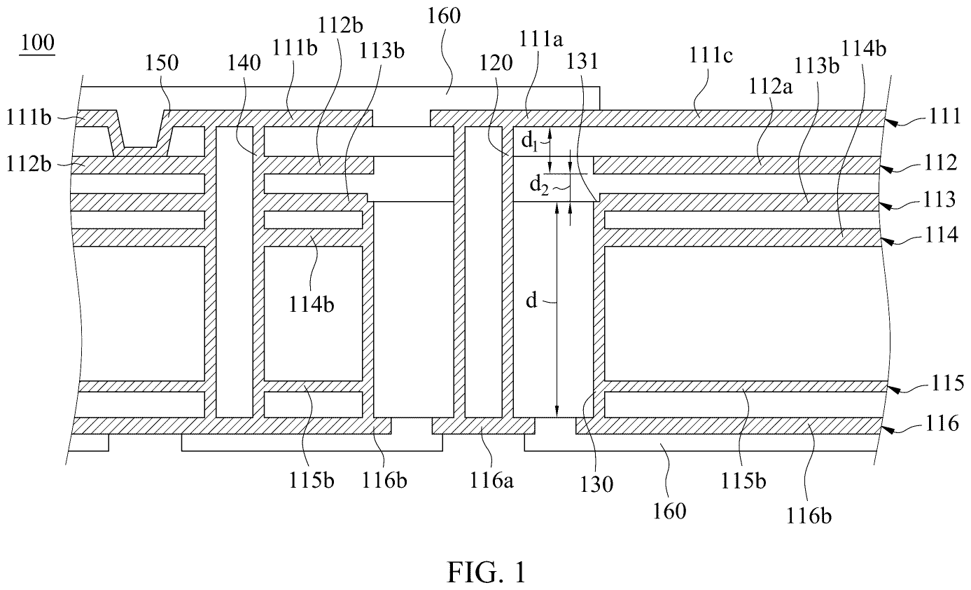

FIG. 1 is a partial sectioned view of a circuit board 100. Referring to FIG. 1, the circuit board 100 includes multiple wiring layers, a conductor pole 120, a metal wall 130, a plated through hole 140, a blind via hole 150, and solder mask layers 160, where the above wiring layers are illustrated by six wiring layers 111˜116, for example, but is not limited to this. The six wiring layers 111˜116 stacked, in order from top to bottom, are the wiring layer 111, the wiring layer 112, the wiring layer 113, the wiring layer 114, the wiring layer 115, and the wiring layer 116.

The wiring layer 111 includes a signal portion 111a, a ground portion 111b, and an antenna portion 111c. The signal portion 111a is electrically connected to the antenna portion 111c. The wiring layer 112 includes a signal portion 112a and a ground portion 112b. The wiring layer 113 includes a ground portion 113b. The wiring layer 114 includes a ground portion 114b. The wiring layer 115 includes a ground portion 115b. The wiring layer 116 includes a chip pad 116a and a ground portion 116b.

The conductor pole 120 penetrates the wiring layers 111˜116, and is connected to the wiring layer 111 and the wiring layer 116. The conductor pole 120 is electrically connected to the signal portion 111a of the wiring layer 111 and the chip pad 116a of the wiring layer 116. Therefore, the signal in the antenna portion 111c can be transmitted to a chip (not shown) soldered to the chip pad 116a by the conductor pole 120. The conductor pole 120 may be a solid or hollow structure, and is illustrated by the hollow conductor pole 120, for example.

The metal wall 130 extends from the wiring layer 113 to the wiring layer 116, and surrounds the conductor pole 120. The external face of the metal wall 130 is connected to the wiring layers 113˜116 to be electrically connected to the ground portions 113b˜116b. The metal wall 130 can shield interference between the signals transmitted in the conductor pole 120 and in the wiring layers 113˜116. The metal wall 130 and the conductor pole 120 form a coaxial via. For example, the top of the metal wall 130 forms a cavity 131. The cavity 131 is similar to a step. That is, in the partial sectioned view of FIG. 1, the angle between the top and the side of the metal wall 130 is substantially a right angle. In some other embodiments, the top of the metal wall 130 does not form the cavity 131.

The plated through hole 140 penetrates the wiring layers 111˜116 and is electrically connected to the wiring layers 111˜116. The plated through hole 140 is electrically connected to the ground portions 111b˜116b. The structure of the plated through hole 140 is similar to that of the conductor pole 120. In other words, the conductor pole 120 maybe a plated through hole. The blind via hole 150 is formed between the wiring layers 111˜112 and are electrically connected to the ground portions 111b˜112b. For example, the circuit board 100 further includes multiple blind via holes 150, and the blind via holes 150 may surround the conductor pole 120, thereby shielding interference between the signals transmitted in the conductor pole 120 and in the wiring layers 111˜112. The solder mask layers 160 are disposed partial surfaces of the wiring layers 111 and 116 and do not cover the antenna portion 111c.

The electrical parameters of the coaxial via of the circuit board 100 can be obtained by performing a circuit board measurement method using a circuit board measurement kit. The circuit board measurement kit includes a first measurement circuit board, a second measurement circuit board, a third measurement circuit board, and an auxiliary measurement circuit board, in which each of the structures of the first measurement circuit board, the second measurement circuit board, the third measurement circuit board, and the auxiliary measurement circuit board is similar to that of the circuit board 100.

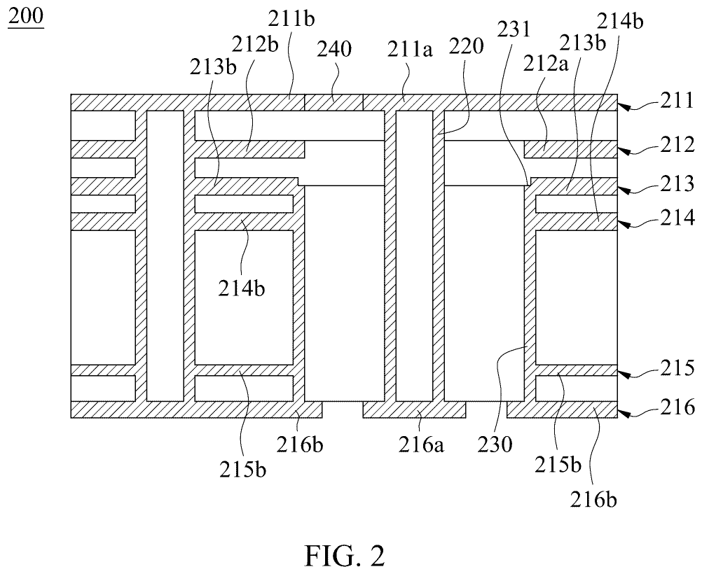

FIG. 2 is a sectioned view of the first measurement circuit board 200 according to at least one embodiment of the present disclosure. Referring to FIG. 2, the first measurement circuit board 200 includes multiple wiring layers 211˜216, a conductor pole 220, a metal wall 230, and a transmission line 240. The six wiring layers 211˜216 stacked, in order from top to bottom, are the wiring layer 211, the wiring layer 212, the wiring layer 213, the wiring layer 214, the wiring layer 215, and the wiring layer 216.

In particular, the materials and thicknesses of the wiring layers 211˜216 are identical to those of the wiring layers 111˜116, and the materials and thicknesses of dielectric layers between the wiring layers 211˜216 are also identical to those of dielectric layers between the wiring layers 111˜116.

The wiring layer 211 includes a signal portion 211a and a ground portion 211b. The wiring layer 212 includes a signal portion 212a and a ground portion 212b. The wiring layer 213 includes a ground portion 213b. The wiring layer 214 includes a ground portion 214b. The wiring layer 215 includes a ground portion 215b. The wiring layer 216 includes a signal portion 216a and a ground portion 216b. The structure of the signal portion 216a is similar to that of the chip pad 116a, that is, the signal portion 216a can be a pad.

The structure of the conductor pole 220 is similar to that of the conductor pole 120, and is electrically connected to the signal portion 211a of the wiring layer 211 and the signal portion 216a of the wiring layer 216. The structure of the metal wall 230 is similar to that of the metal wall 130, and the metal wall 230 surrounds the conductor pole 220. The metal wall 230 is electrically connected to the ground portions 213b˜216b. The top of the metal wall 230 may also form a cavity 231 or may not form a cavity 231, but is not limited to this. The transmission line 240 and the wiring layer 211 are on the same plane, and the surface of the transmission line 240 is flush with that of the wiring layer 211. The transmission line 240 is electrically connected to the conductor pole 220 and the ground portion 211b so that the conductor pole 220 and the ground portion 211b of the wiring layer 211 are electrically conductive.

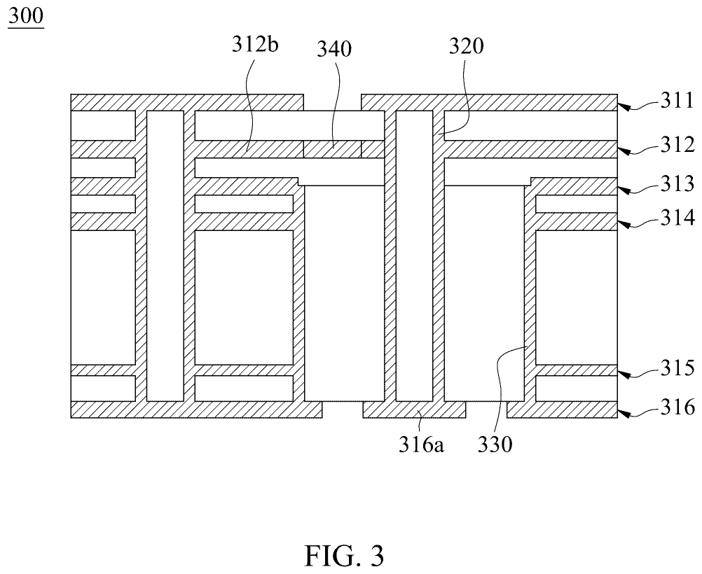

FIG. 3 is a sectioned view of the second measurement circuit board 300 according to at least one embodiment of the present disclosure. Referring to FIG. 3, the second measurement circuit board 300 includes multiple wiring layers 311˜316, a conductor pole 320, a metal wall 330, and a transmission line 340. The six wiring layers 311˜316 stacked, in order from top to bottom, are the wiring layer 311, the wiring layer 312, the wiring layer 313, the wiring layer 314, the wiring layer 315, and the wiring layer 316.

In particular, the structure of the second measurement circuit board 300 is similar to that of the first measurement circuit board 200. The materials and thicknesses of the wiring layers 311˜316 are similar to those of the wiring layers 211˜216, respectively, and the materials and thicknesses of dielectric layers between the wiring layers 311˜316 are also similar to those of the dielectric layers between the wiring layers 211˜216, respectively.

The difference between the second measurement circuit board 300 and the first measurement circuit board 200 is that the transmission line 340 and the wiring layer 312 are on the same plane, and the surface of the transmission line 340 is flush with that of the wiring layer 312. The transmission line 340 is electrically connected to the conductor pole 320 and the ground portion 312b so that the conductor pole 320 and the ground portion 312b of the wiring layer 312 are electrically conductive.

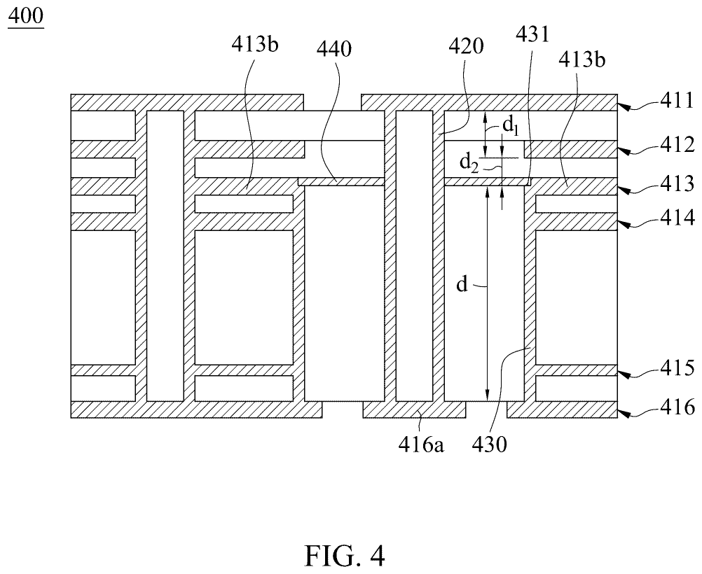

FIG. 4 is a sectioned view of the third measurement circuit board 400 according to at least one embodiment of the present disclosure. Referring to FIG. 4, the third measurement circuit board 400 includes multiple wiring layers 411˜416, a conductor pole 420, a metal wall 430, and a transmission line 440. The six wiring layers 411˜416 stacked, in order from top to bottom, are the wiring layer 411, the wiring layer 412, the wiring layer 413, the wiring layer 414, the wiring layer 415, and the wiring layer 416.

In particular, the structure of the third measurement circuit board 400 is also similar to that of the first measurement circuit board 200. The materials and thicknesses of the wiring layers 411˜416 are similar to those of the wiring layers 211˜216, respectively, and the materials and thicknesses of dielectric layers between the wiring layers 411˜416 are also similar to those of the dielectric layers between the wiring layers 211˜216, respectively. The top of the metal wall 430 may also form a cavity 431 or may not form a cavity 431, but is not limited to this.

The difference between the third measurement circuit board 400 and the first measurement circuit board 200 is that when the top of the metal wall 430 forms the cavity 431, the transmission line 440 is connected to the cavity 431 of the metal wall 430 and the conductor pole 420, and the surface of the transmission line 440 is flush with that of the wiring layer 413. When the top of the metal wall 430 does not form the cavity 431, the transmission line 440 is directly connected to the side of the metal wall 430 and the conductor pole 420, and the surface of the transmission line 440 is flush with that of the wiring layer 413. The transmission line 440 is electrically connected to the conductor pole 420, the ground portion 413b, and the metal wall 430 so that the conductor pole 420 and the ground portion 413b of the wiring layer 413 are electrically conductive.

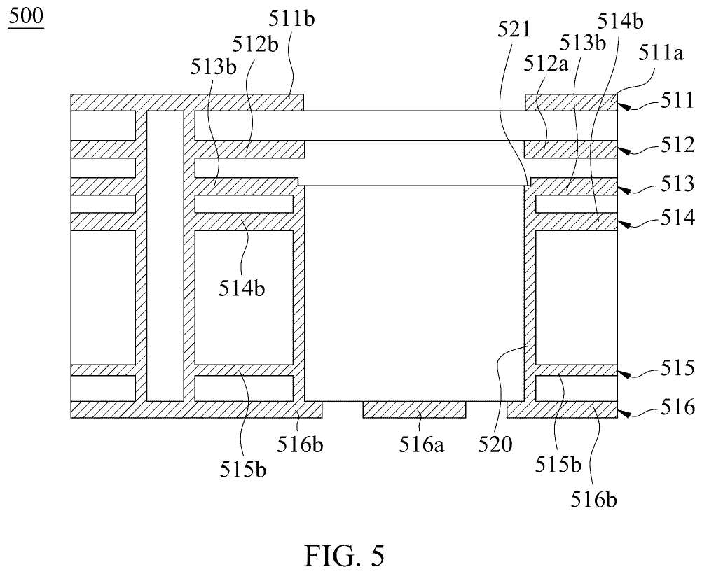

FIG. 5 is a sectioned view of the auxiliary measurement circuit board 500 according to at least one embodiment of the present disclosure. Referring to FIG. 5, the auxiliary measurement circuit board 500 includes multiple measurement wiring layers 511˜516 and a measurement metal wall 520. The six measurement wiring layers 511˜516, in order from top to bottom, are the measurement wiring layer 511, the measurement wiring layer 512, the measurement wiring layer 513, the measurement wiring layer 514, the measurement wiring layer 515, and the measurement wiring layer 516.

In particular, the thickness of the auxiliary measurement circuit board 500 is similar to that of the first measurement circuit board 200. The materials and thicknesses of the measurement wiring layers 511˜516 are similar to those of the wiring layers 211˜216, respectively, and are also similar to those of the wiring layers 111˜116, respectively. The materials and thicknesses of dielectric layers between the measurement wiring layers 511˜516 are also similar to those of the dielectric layers between the wiring layers 211˜216, respectively, and are also similar to those of the dielectric layers between the wiring layers 111˜116, respectively.

The measurement wiring layer 511 includes a signal portion 511a and a ground portion 511b. The measurement wiring layer 512 includes a signal portion 512a and a ground portion 512b. The measurement wiring layer 513 includes a ground portion 513b. The measurement wiring layer 514 includes a ground portion 514b. The measurement wiring layer 515 includes a ground portion 515b. The measurement wiring layer 516 includes a signal portion 516a and a ground portion 516b. The structure of the signal portion 516a is similar to that of the chip pad 116a, that is, the signal portion 516a can be a pad. The measurement metal wall 520 extends from the measurement wiring layer 513 to the measurement wiring layer 516, and is electrically connected to the ground portions 513b˜516b of the measurement wiring layers 513˜516. The top of the measurement metal wall 520 may also form a cavity 521 or may not form a cavity 521, but is not limited to this.

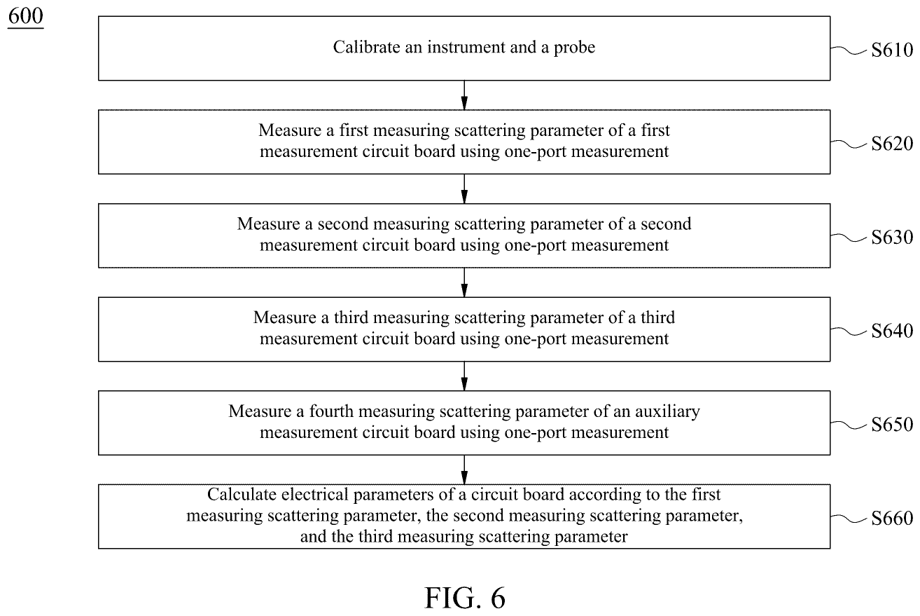

FIG. 6 is a flowchart of a circuit board measurement method 600 according to at least one embodiment of the present disclosure. The circuit board measurement method 600 shown below is to measure the first measurement circuit board 200, the second measurement circuit board 300, the third measurement circuit board 400, and the auxiliary measurement circuit board 500 as shown in FIGS. 2 to 5 to obtain electrical parameters indirectly according to measurement results.

Referring to FIG. 6, an instrument and a probe are first calibrated in step S610, so that the measuring reference is then calibrated to the end of the probe, in which the instrument may be a network analyzer, and the probe may be a GSG (Ground Signal Ground) probe, a GS (Ground Signal) probe, a SG (Signal Ground) probe or SGS (Signal Ground Signal) probe.

In the embodiment, using the network analyzer and the GSG probe to measure. In details, a calibration kit is probed by the GSG probe to perform a one-port calibration, in which the calibration kit contains a short accessory, an open accessory, and a load accessory.

Referring to FIGS. 2 and 6, a first measuring scattering parameter of the first measurement circuit board 200 is then measured by the probe using one-port measurement in step S620. Specifically, the signal portion 216a of the first measurement circuit board 200 is probed by the probe to obtain the first measuring scattering parameter, where the first measuring scattering parameter is an input port reflection coefficient S11. That is, a measuring signal is input into the signal portion 216a and a reflected signal is also measured in the signal portion 216a by the probe.

Referring to FIGS. 3 and 6, a second measuring scattering parameter of the second measurement circuit board 300 is then measured by the probe using one-port measurement in step S630. In details, the signal portion 316a of the second measurement circuit board 300 is probed by the probe to obtain the second measuring scattering parameter, where the second measuring scattering parameter is also an input port reflection coefficient S11. That is, a measuring signal is input into the signal portion 316a and a reflected signal is also measured in the signal portion 316a by the probe.

Referring to FIGS. 4 and 6, a third measuring scattering parameter of the third measurement circuit board 400 is then measured by the probe using one-port measurement in step S640. In details, the signal portion 416a of the third measurement circuit board 400 is probed by the probe to obtain the third measuring scattering parameter, where the third measuring scattering parameter is also an input port reflection coefficient S11. That is, a measuring signal is input into the signal portion 416a and a reflected signal is also measured in the signal portion 416a by the probe.

Referring to FIGS. 5 and 6, a fourth measuring scattering parameter of the auxiliary measurement circuit board 500 is then measured by the probe using one-port measurement in step S650. In details, the signal portion 516a of the auxiliary measurement circuit board 500 is probed by the probe to obtain the fourth measuring scattering parameter, where the fourth measuring scattering parameter is also an input port reflection coefficient S11. That is, a measuring signal is input into the signal portion 516a and a reflected signal is also measured in the signal portion 516a by the probe.

It is worth mentioning that the above steps S620 to S650 do not limit the order, and step S650 can be performed first to measure the auxiliary measurement circuit board 500, and then steps S620 to S640 are performed to measure the first measurement circuit board 200 to the third measurement circuit board 400.

Further, with reference to FIGS. 1 and 5, compared to the circuit board 100, the auxiliary measurement circuit board 500 does not have the conductor pole, so that the signal portion 516a and the signal portion 511a form an open circuit. Therefore, an equivalent circuit of the auxiliary measurement circuit board 500, where the signal portion 516a is an input point, is an equivalent capacitance, and the fourth measuring scattering parameter in the measurement wiring layer 516 is the measuring scattering parameter of the equivalent capacitance. In particular, the equivalent circuit of the signal portion 516a of the auxiliary measurement circuit board 500 can correspond to an equivalent capacitance formed by the chip pad 116a of the circuit board 100. In this way, the fourth measuring scattering parameter can correspond to the measuring scattering parameter of the equivalent capacitance of the circuit board 100.

Referring to FIGS. 1 and 4, in the third measurement circuit board 400, since the transmission line 440 is electrically connected to the conductor pole 420, the ground portion 413b, and the metal wall 430, and the surface of the transmission line 440 is flush with that of the wiring layer 413, the position of the conductor pole 420 corresponding to the surface of the wiring layer 413 forms a short circuit. Therefore, an equivalent circuit of the third measurement circuit board 400, where the signal portion 416a is an input point, is an equivalent coaxial via, and the third measuring scattering parameter between the transmission line 440 and the wiring layer 416 is the measuring scattering parameter of the equivalent coaxial via. In particular, the equivalent circuit of the third measurement circuit board 400 can correspond to the coaxial via (the metal wall 130 and the partial conductor pole 120 in the metal wall 130) of the circuit board 100. In this way, the third measuring scattering parameter can correspond to the measuring scattering parameter of the coaxial via of the circuit board 100.

Referring to FIGS. 1 and 3, in the second measurement circuit board 300, since the transmission line 340 is electrically connected to the conductor pole 320 and the ground portion 312b, and the surface and bottom of the transmission line 340 are flush with those of the wiring layer 312, respectively, the position of the conductor pole 320 corresponding to the wiring layer 312 forms a short circuit. Therefore, an equivalent circuit of the second measurement circuit board 300, where the signal portion 316a is an input point, is an equivalent coaxial via connected to an equivalent inductance, and the second measuring scattering parameter between the transmission line 340 and the wiring layer 316 is the measuring scattering parameter of the equivalent coaxial via and the equivalent inductance. In particular, the equivalent circuit of the second measurement circuit board 300 can correspond to the coaxial via and the equivalent inductance of circuit board 100.

It should be noted that, in this embodiment, the equivalent inductance is from the cavity 131 of the metal wall 130 extending to the bottom of the wiring layer 112. That is, the equivalent inductance is from the position of the metal wall 130, which corresponds to the bottom of the transmission line 440 in FIG. 4, extending to the bottom of the wiring layer 112. In this way, the second measuring scattering parameter can correspond to the measuring scattering parameter of the coaxial via and the equivalent inductance of circuit board 100.

Referring to FIGS. 1 and 2, in the first measurement circuit board 200, since the transmission line 240 is electrically connected to the conductor pole 220 and the ground portion 211b, and the surface and bottom of the transmission line 240 are flush with those of the wiring layer 211, respectively, the position of the conductor pole 220 corresponding to the wiring layer 211 forms a short circuit. Therefore, an equivalent circuit of the first measurement circuit board 200, where the signal portion 216a is an input point, is an equivalent coaxial via connected to an equivalent inductance, and the first measuring scattering parameter between the transmission line 240 and the wiring layer 216 is the measuring scattering parameter of the equivalent coaxial via and the equivalent inductance. In particular, the equivalent circuit of the first measurement circuit board 200 can correspond to the coaxial via and the equivalent inductance of circuit board 100.

It should be noted that, in this embodiment, the equivalent inductance is from the cavity 131 of the metal wall 130 extending to the bottom of the wiring layer 111. That is, the equivalent inductance is from the position of the metal wall 130, which corresponds to the bottom of the transmission line 440 in FIG. 4, extending to the bottom of the wiring layer 111. In this way, the first measuring scattering parameter can correspond to the measuring scattering parameter of the coaxial via and the equivalent inductance of circuit board 100.

Referring to FIG. 6, in step S660, a processor then calculates the electrical parameters of the coaxial via, such as a characteristic impedance value, a first terminal inductance impedance value, a second terminal inductance impedance value and a propagation constant, according to the first measuring scattering parameter, the second measuring scattering parameter, and the third measuring scattering parameter, where the first terminal inductance impedance value is the impedance of a first equivalent inductance that is connected to the end of the coaxial via (i.e., the equivalent inductance from the cavity 131 of the metal wall 130 extending to the bottom of the wiring layer 111), and the second terminal inductance impedance value is the impedance of a second equivalent inductance that is connected to the end of the coaxial via (i.e., the equivalent inductance from the cavity 131 of the metal wall 130 extending to the bottom of the wiring layer 112). It should be noted that, the processor has computational functions, and may be, but is not limited to, the processor in the network analyzer or in a computer.

The structure of the first measurement circuit board 200 is similar in that the conductor pole 120 of the circuit board 100 is connected to ground at locations corresponding to the wiring layer 111. The structure of the second measurement circuit board 300 is similar in that the conductor pole 120 is connected to ground at locations corresponding to the wiring layer 112 of the circuit board 100. The structure of the third measurement circuit board 400 is similar in that the conductor pole 120 is connected to ground at locations corresponding to the wiring layer 113 of the circuit board 100. The structure of the auxiliary measurement circuit board 500 is similar in that the conductor pole 120 and the wiring layer 116 of the circuit board 100 form an open circuit. Therefore, in the condition without taking into account the manufacturing deviation, the first measuring scattering parameter, the second measuring scattering parameter, the third measuring scattering parameter, and the fourth measuring scattering parameter are similar to the measurement results in the equivalent circuits for the circuit board 100.

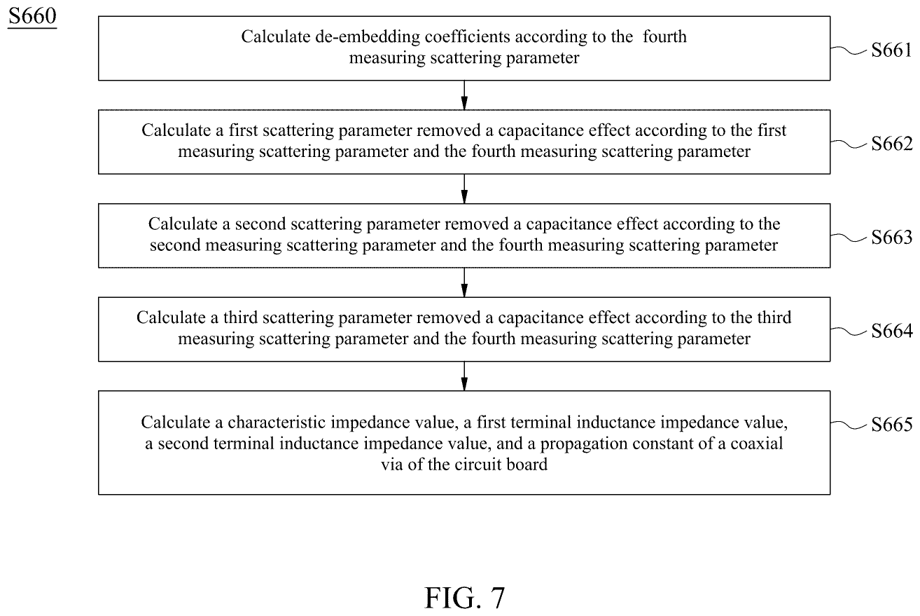

FIG. 7 is a flowchart of sub-steps S661˜S665 of step S660 of the circuit board measurement method 600 of FIG. 6. Referring to FIG. 7, step S660 includes sub-steps S661˜S665. In sub-step S661, the processor calculates de-embedding coefficients according to the fourth measuring scattering parameter. The following are the formulas for the de-embedding coefficients:

$${e}_{11} = \frac{- 1 + {Γ}_{pad}}{3 + {Γ}_{pad}} ;$$

$${e}_{21} = \frac{2 ( 1 + {Γ}_{pad} )}{3 + {Γ}_{pad}} ;$$

where e₁₁, e₂₁ are de-embedding coefficients, and Γ_{pad} is the fourth measuring scattering parameter.

In sub-step S662, the processor then calculates a first scattering parameter removed the capacitance effect according to the first measuring scattering parameter and the fourth measuring scattering parameter, where the fourth measuring scattering parameter is used to calculate the de-embedding coefficients. The following is the formula for the first scattering parameter:

$${Γ}_{L 1} = \frac{{Γ}_{L 1 , embed} - {e}_{11}}{{e}_{21}^{2} + {e}_{11} ( {Γ}_{L 1 , embed} - {e}_{11} )} ;$$

where Γ_{L1} is the first scattering parameter, and Γ_{L1,embed} is the first measuring scattering parameter.

In sub-step S663, the processor then calculates a second scattering parameter removed the capacitance effect according to the second measuring scattering parameter and the fourth measuring scattering parameter, where the fourth measuring scattering parameter is used to calculate the de-embedding coefficients. The following is the formula for the second scattering parameter:

$${Γ}_{L 2} = \frac{{Γ}_{L 2 , embed} - {e}_{11}}{{e}_{21}^{2} + {e}_{11} ( {Γ}_{L 2 , embed} - {e}_{11} )} ;$$

where Γ_{L2} is the second scattering parameter, and Γ_{L2,embed} is the second measuring scattering parameter.

In sub-step S664, the processor then calculates a third scattering parameter removed the capacitance effect according to the third measuring scattering parameter and the fourth measuring scattering parameter, where the fourth measuring scattering parameter is used to calculate the de-embedding coefficients. The following is the formula for the third scattering parameter:

$${Γ}_{L 3} = \frac{{Γ}_{L 3 , embed} - {e}_{11}}{{e}_{21}^{2} + {e}_{11} ( {Γ}_{L 3 , embed} - {e}_{11} )} ;$$

where Γ_{L3} is the third scattering parameter, and Γ_{L3,embed} is the third measuring scattering parameter.

In sub-step S665, the processor then calculates the characteristic impedance value, the first terminal inductance impedance value, the second terminal inductance impedance value, and the propagation constant of the coaxial via of the circuit board 100 according to the first scattering parameter, the second scattering parameter, the third scattering parameter, a coaxial via length d, a first distance d₁, and a second distance d₂. In particular, the coaxial via length d is defined as the length of the equivalent coaxial via, and the sum of the first distance d₁ and the second distance d₂ is defined as the length of the first equivalent inductance, and the second distance d₂ is defined as the length of the second equivalent inductance. As shown for the third measurement circuit board 400 in FIG. 4, the coaxial via length d is the length from the bottom of the metal wall 430 extending to the bottom of the transmission line 440; the second distance d₂ is the length from the bottom of the transmission line 440 extending to the bottom of the wiring layer 412; the first distance d₁ is the length from the bottom of the wiring layer 412 extending to the bottom of the wiring layer 411.

The following are the formulas for the characteristic impedance value, the first terminal inductance impedance value, the second terminal inductance impedance value, and the propagation constant of the coaxial via:

$${Z}_{c} = 50 \sqrt{\frac{( {Z}_{L} / 50 ) ( 1 + {Γ}_{L 1} ) ( 1 + {Γ}_{L 3} )}{2 ( {Γ}_{L 3} - {Γ}_{L 2} ) + ( {Z}_{L} / 50 ) ( 1 - {Γ}_{L 2} ) ( 1 - {Γ}_{L 3} )}} ;$$

$${Z}_{L 1} = {pZ}_{L 2} ;$$

$${Z}_{L 2} = 50 \frac{p ( 1 + {Γ}_{L 1} ) ( {Γ}_{L 2} - {Γ}_{L 3} ) + ( 1 + {Γ}_{L 2} ) ( {Γ}_{L 3} - {Γ}_{L 1} )}{p ( 1 - {Γ}_{L 3} ) ( {Γ}_{L 1} - {Γ}_{L 2} )} ;$$

$$p = \frac{{d}_{1} + {d}_{2}}{{d}_{2}} ;$$

$$γ = \frac{ln ( t )}{d} ;$$

$$t = {e}^{γ d} = \sqrt{\frac{Γ {Γ}_{L 3} - 1}{{Γ}_{L 3} - Γ}} ;$$

$$Γ = \frac{{Z}_{c} - 50}{{Z}_{c} + 50} ;$$

where Z_{c} is the characteristic impedance value, and Z_{L1} is the first terminal inductance impedance value, and Z_{L2} is the second terminal inductance impedance value, and p is the ratio of the length of the first equivalent inductance to the length of the second equivalent inductance, and γ is the propagation constant, and t is the communication factor, and Γ is the reflection coefficient of the coaxial via.

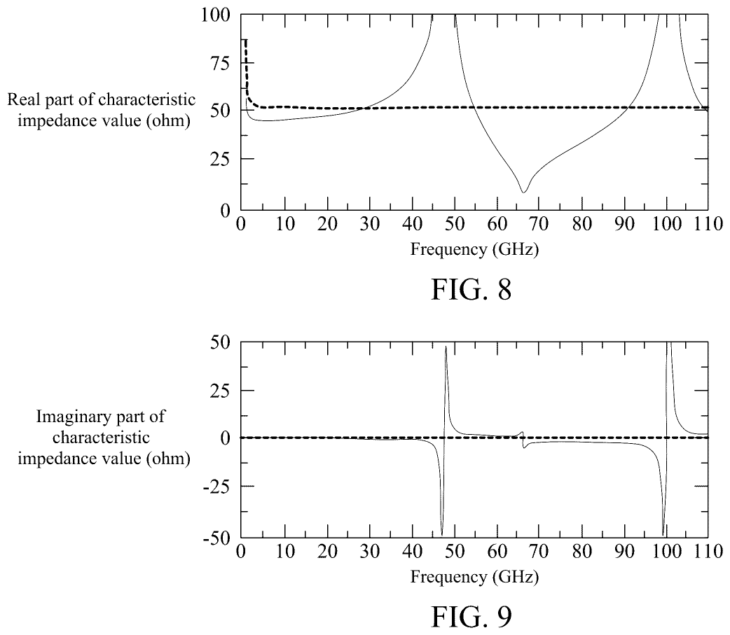

FIGS. 8 and 9 are calculation results of real parts and imaginary parts, respectively, of the characteristic impedance values of the circuit board 100 in FIG. 1. Referring to FIGS. 8 and 9, X-axes represent the frequencies to which each real part and each imaginary part of each characteristic impedance value corresponds, respectively, and Y-axes represent each real part and each imaginary part of each characteristic impedance value, respectively. Solid lines are the calculation results without removing the capacitance effects, and dashed lines are the calculation results with removing the capacitance effects.

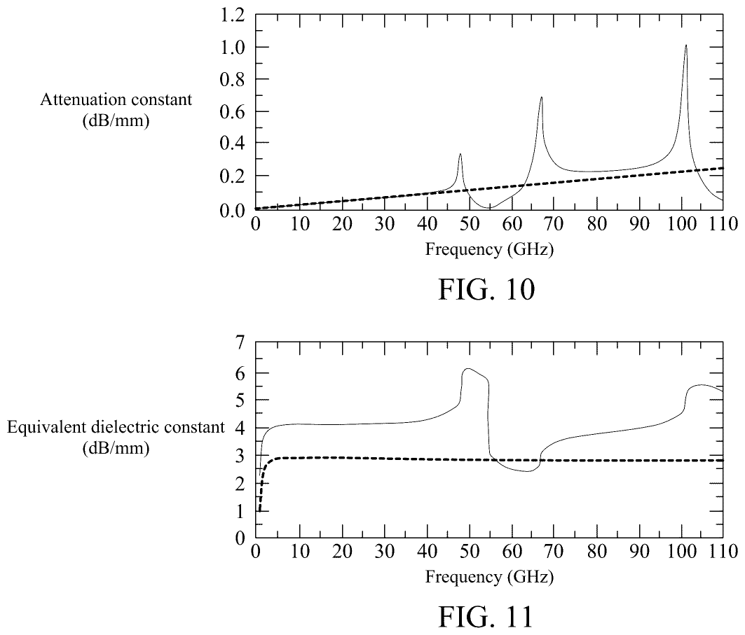

FIGS. 10 and 11 are calculation results of attenuation constants and equivalent dielectric constants, respectively, corresponding to the propagation constants of the circuit board 100 in FIG. 1 as calculated. Referring to FIGS. 10 and 11, X-axes represent the frequencies to which each attenuation constant and each equivalent dielectric constant correspond, respectively, and Y-axes represent each attenuation constant and each equivalent dielectric constant, respectively. Solid lines are the calculation results without removing the capacitance effects, and dashed lines are the calculation results with removing the capacitance effects.

From FIGS. 8 to 11, it can be seen that by removing the capacitance effects and the inductance effects from above steps, stable and converging results can be calculated in the frequency range from 5 GHz to 110 GHz and approximate the electrical parameters of the coaxial via designed. Therefore, the circuit board measurement kit and the circuit board measurement method of the present disclosure cooperate, which can actually calculate the electrical parameters of the coaxial via of the circuit board 100, thereby verifying conditions such as the impedance matching of the coaxial via, and variations in the amplitudes and phases of the electromagnetic waves propagating in the coaxial via. In addition, the circuit board measurement kit and the circuit board measurement method of the present disclosure can also be applied to, but are not limited to, four wiring layers, five wiring layers, or more than six wiring layers of the circuit board. Each of the circuit boards may also use the first measurement circuit board 200, the second measurement circuit board 300, the third measurement circuit board 400, and the auxiliary measurement circuit board 500 for measurement.

It is worth mentioning that, the circuit board measurement kit and the circuit board measurement method of the present disclosure can also be applicable to the case where the signal portion 111a of the wiring layer 111 of the circuit board 100 is a single pad or a transmission line structure. When the signal portion 111a is the single pad, the coaxial via and the single pad form a shape I structure, while when the signal portion 111a is the transmission line structure, the coaxial via and the transmission line structure form a shape L structure. By using the circuit board measurement kit and the circuit board measurement method of the present disclosure, the electrical parameters of the shape I structure or the coaxial via of the shape L structure of the circuit board can be obtained, and the electrical parameters of the transmission line structure of the shape L structure of the circuit board can be obtained by referring to patents such as Taiwan Patents Publication No. 1426289, 1463146, 1463147 and 1747750. In addition, the circuit board measurement kit and the circuit board measurement method of the present disclosure can also be applied to the technical fields such as semiconductor silicon perforation, glass perforation, 3D wafer or high-density package, compared to the double-side and two-port measurement, thereby providing convenient configuration and reliable verification tools and methods.

Consequently, the circuit board measurement kit and the circuit board measurement method according to the above embodiments can provide the one-side and the one-port measurement to indirectly calculate the electrical parameters of the coaxial via of the circuit board, which simplifies the configuration of the equipment, the necessary functions of the instrument, and the complexity of the measurement, and provides reliable verification tools and methods.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A circuit board measurement kit, comprising:
three measurement circuit boards, wherein each of the three measurement circuit boards comprises:
four wiring layers stacked, wherein the four wiring layers, in order from top to bottom, are a first wiring layer, a second wiring layer, a third wiring layer, and a fourth wiring layer;
a conductor pole penetrating the four wiring layers and connected to the first wiring layer and the fourth wiring layer;
a metal wall extending from the third wiring layer to the fourth wiring layer and surrounding the conductor pole; and
a transmission line electrically connected to the conductor pole, wherein a surface of one of the four wiring layers is flush with a surface of the transmission line,
wherein in a first of the measurement circuit boards, the surface of the transmission line is flush with a surface of the first wiring layer, and the transmission line is electrically connected to a ground portion of the first wiring layer, wherein there is a first measuring scattering parameter between the transmission line and the fourth wiring layer,
wherein in a second of the measurement circuit boards, the surface of the transmission line is flush with a surface of the second wiring layer, and the transmission line is electrically connected to a ground portion of the second wiring layer, wherein there is a second measuring scattering parameter between the transmission line and the fourth wiring layer,
wherein in a third of the measurement circuit boards, the surface of the transmission line is flush with a surface of the third wiring layer, and the transmission line is electrically connected to the metal wall, wherein there is a third measuring scattering parameter between the transmission line and the fourth wiring layer, and
wherein an electrical parameter of a coaxial via of a circuit board is calculated according to the first measuring scattering parameter, the second measuring scattering parameter, and the third measuring scattering parameter.

2. The circuit board measurement kit of claim 1, further comprising:
an auxiliary measurement circuit board comprising:
four measurement wiring layers stacked, wherein the four measurement wiring layers, in order from top to bottom, are a first measurement wiring layer, a second measurement wiring layer, a third measurement wiring layer, and a fourth measurement wiring layer; and
a measurement metal wall extending from the third measurement wiring layer to the fourth measurement wiring layer,
wherein there is a fourth measuring scattering parameter in the fourth measurement wiring layer, and the electrical parameter of the coaxial via is further calculated according to the fourth measuring scattering parameter.

3. The circuit board measurement kit of claim 2, wherein a thickness of the auxiliary measurement circuit board is identical to a thickness of each of the measurement circuit boards.

4. The circuit board measurement kit of claim 2, wherein a thickness of the first measurement wiring layer is identical to a thickness of each of the first wiring layers.

5. The circuit board measurement kit of claim 2, wherein a thickness of the second measurement wiring layer is identical to a thickness of each of the second wiring layers.

6. The circuit board measurement kit of claim 2, wherein a thickness of the third measurement wiring layer is identical to a thickness of each of the third wiring layers.

7. The circuit board measurement kit of claim 2, wherein a thickness of the fourth measurement wiring layer is identical to a thickness of each of the fourth wiring layers.

8. The circuit board measurement kit of claim 1, wherein in the first of the measurement circuit boards, the transmission line and the first wiring layer are on the same plane.

9. The circuit board measurement kit of claim 1, wherein in the second of the measurement circuit boards, the transmission line and the second wiring layer are on the same plane.

10. The circuit board measurement kit of claim 1, wherein in the third of the measurement circuit boards, a top of the metal wall has a cavity, and the transmission line is connected to the cavity and the surface of the transmission line is flush with the surface of the third wiring layer.

11. A circuit board measurement method, comprising:
measuring a first measuring scattering parameter of a first measurement circuit board using one-port measurement;
measuring a second measuring scattering parameter of a second measurement circuit board using one-port measurement;
measuring a third measuring scattering parameter of a third measurement circuit board using one-port measurement; and
calculating a characteristic impedance value, a terminal inductance impedance value, and a propagation constant of a coaxial via of a circuit board according to the first measuring scattering parameter, the second measuring scattering parameter, and the third measuring scattering parameter.

12. The circuit board measurement method of claim 11, wherein a step of calculating the characteristic impedance value, the terminal inductance impedance value, and the propagation constant of the coaxial via, comprises:
measuring a fourth measuring scattering parameter of an auxiliary measurement circuit board using one-port measurement;
calculating a first scattering parameter removed a capacitance effect according to the first measuring scattering parameter and the fourth measuring scattering parameter;
calculating a second scattering parameter removed a capacitance effect according to the second measuring scattering parameter and the fourth measuring scattering parameter;
calculating a third scattering parameter removed a capacitance effect according to the third measuring scattering parameter and the fourth measuring scattering parameter; and
calculating the characteristic impedance value, the terminal inductance impedance value, and the propagation constant of the coaxial via according to the first scattering parameter, the second measuring scattering parameter, and the third scattering parameter.

13. The circuit board measurement method of claim 11, wherein the characteristic impedance value, the terminal inductance impedance value, and the propagation constant are further obtained according to a coaxial via length, a first distance, and a second distance,
wherein an equivalent circuit of the third measurement circuit board is an equivalent coaxial via, and the coaxial via length is defined as a length of the equivalent coaxial via,
wherein an equivalent circuit of the first measurement circuit board is that the equivalent coaxial via is connected to a first equivalent inductance,
wherein an equivalent circuit of the second measurement circuit board is that the equivalent coaxial via is connected to a second equivalent inductance,
wherein a sum of the first distance and the second distance is defined as a length of the first equivalent inductance, and
wherein the second distance is defined as a length of the second equivalent inductance.

14. The circuit board measurement method of claim 13, wherein the third measurement circuit board comprises:
four wiring layers stacked, wherein the four wiring layers, in order from top to bottom, are a first wiring layer, a second wiring layer, a third wiring layer, and a fourth wiring layer;
a conductor pole penetrating the four wiring layers and connected to the first wiring layer and the fourth wiring layer;
a metal wall extending from the third wiring layer to the fourth wiring layer and surrounding the conductor pole; and
a transmission line electrically connected to the conductor pole and the metal wall, and a surface of the transmission line flush with a surface of the third wiring layer, and
wherein the coaxial via length is a length from a bottom of the metal wall extending to a bottom of the transmission line.

15. The circuit board measurement method of claim 14, wherein the second distance is a length from the bottom of the transmission line extending to a bottom of the second wiring layer.

16. The circuit board measurement method of claim 14, wherein the first distance is a length from a bottom of the second wiring layer extending to a bottom of the first wiring layer.
